(19) United States
(12) Patent Application Publication
(10) Pub. No.: US 2025/0096095 A1
(43) Pub. Date: Mar. 20, 2025

(54) Semiconductor Device and Methods of Making and Using Dummy Vias to Reduce Short-Circuits Between Solder Bumps

(71) Applicant: STATS ChipPAC Pte. Ltd., Singapore (SG)

(72) Inventors: Peik Eng Ooi, Singapore (SG); Beng Yee Teh, Singapore (SG); Linda Pei Ee Chua, Singapore (SG)

(73) Assignee: STATS ChipPAC Pte. Ltd., Singapore (SG)

(21) Appl. No.: 18/468,957

(22) Filed: Sep. 18, 2023

(51) Int. Cl. H01L 23/498; H01L 21/48; H01L 23/00; H01L 23/31

(52) U.S. Cl. CPC H01L 23/49838; H01L 21/4853; H01L 23/3128; H01L 23/49816; H01L 24/13; H01L 24/16; H01L 2224/13021; H01L 2224/13024; H01L 2224/16227

(57) ABSTRACT

A semiconductor device has a semiconductor die and an encapsulant deposited over the semiconductor die to form a reconstituted wafer. A first insulating layer is formed over the reconstituted wafer. A first dummy opening is formed in the first insulating layer. A first conductive layer is formed on the first insulating layer including a first contact pad over the first dummy opening.

### FIELD OF THE INVENTION

The present invention relates in general to semiconductor devices and, more particularly, to a semiconductor device and methods of making and using dummy vias to reduce short-circuits between solder bumps.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, power conversion, photo-electric, and creating visual images for television displays. Semiconductor devices are found in the fields of communications, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. As the sizes of semiconductor devices shrink, the density of interconnect bumps on the semiconductor devices increases. The smaller pitches between bumps increase vulnerability of the bumps to short circuits. Bumps that are close to each other may reflow into each other during manufacturing, causing an undesirable short circuit between terminals of the device.

FIG. 1a shows an example of two adjacent solder bumps 50a and 50b. Bumps 50a and 50b are formed over a substrate 60 with a redistribution interconnect structure formed by insulating layer 62, conductive layer 64, and insulating layer 66. Openings are formed in insulating layer 66 to expose contact pads of conductive layer 64. Bumps 50a and 50b are properly reflowed onto their respective individual contact pads. However, FIG. 1b shows two adjacent bumps that have been inadvertently and undesirably reflowed together into bump 70 causing a short circuit.

One way that a short circuit happens is that adjacent bumps, when first placed on conductive layer 64 in the openings of insulating layer 66 as balls of solder, may roll toward each other. The opening of insulating layer 64 does not provide sufficient topology to hold the ball in place before reflow. Solder balls are able to roll out of the openings in insulating layer 64 or may remain within the insulating layer openings but roll close enough to reflow into each other. Therefore, a need exists for semiconductor devices and methods to reduce short circuits between adjacent solder bumps.

### BRIEF DESCRIPTION OF THE DRAWINGS

FIGS. 1a and 1b illustrate a short circuit between adjacent solder bumps;

FIGS. 2a-2c illustrate a semiconductor wafer with a plurality of semiconductor die separated by a saw street;

FIGS. 3a-3e illustrate a process of forming a semiconductor package with a reconstituted wafer and a build-up interconnect structure;

FIGS. 4a-4h illustrate a process of forming the build-up interconnect structure with dummy vias and extra capture pads to reduce short-circuits;

FIGS. 5a-5f illustrate a second embodiment of forming the build-up interconnect structure with dummy vias and capture pads;

FIGS. 6a-6c illustrate embodiments of dummy vias formed under redistribution layer contact pads;

FIGS. 7a-7d illustrate forming the dummy vias at different heights of the build-up interconnect structure stack;

FIGS. 8a-8c illustrate options for embodiments with different pitches within different areas of the device or reconstituted wafer; and

FIGS. 9a and 9b illustrate integrating the semiconductor packages into an electronic device.

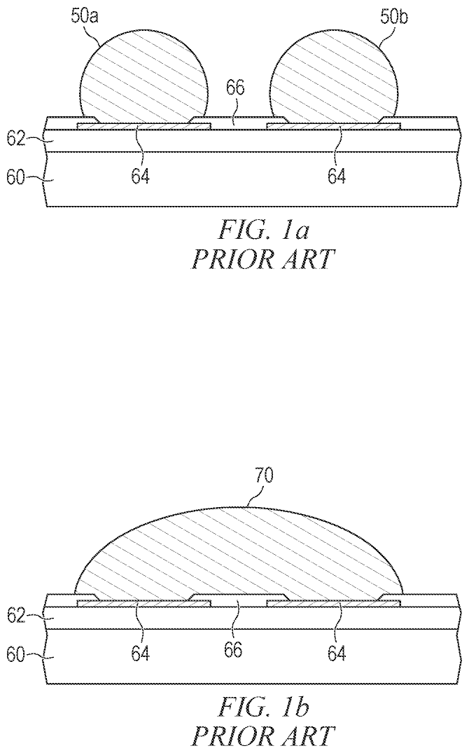

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the semiconductor package. The electrical connections can be made with conductive layers, bumps, stud bumps, conductive paste, or wirebonds. An encapsulant or other molding material is deposited over the semiconductor package to provide physical support and electrical isolation. The finished semiconductor package is then inserted into an electrical system and the functionality of the semiconductor device is made available to the other system components.

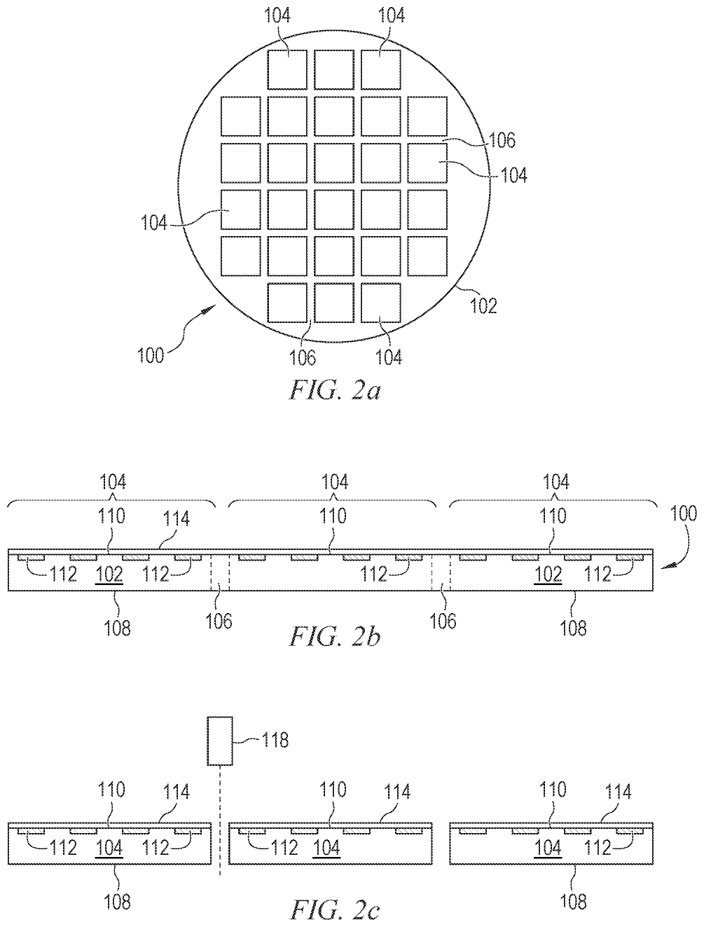

FIG. 2a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 2b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuit (ASIC), memory, power device, or other signal processing circuit. Semiconductor die 104 may also contain integrated passive devices (IPDs), such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

A passivation layer 114 is formed over active surface 110. Passivation layer 114 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Passivation layer 114 can be formed using PVD, CVD, printing, lamination, spin coating, spray coating, sintering, or thermal oxidation. Passivation layer 114 provides a protective coating for active surface 110 and contact pads 112 during subsequent handling and processing. Any insulating or passivation layer mentioned below can be formed using any of the materials or methods described for passivation layer 114.

In FIG. 2c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

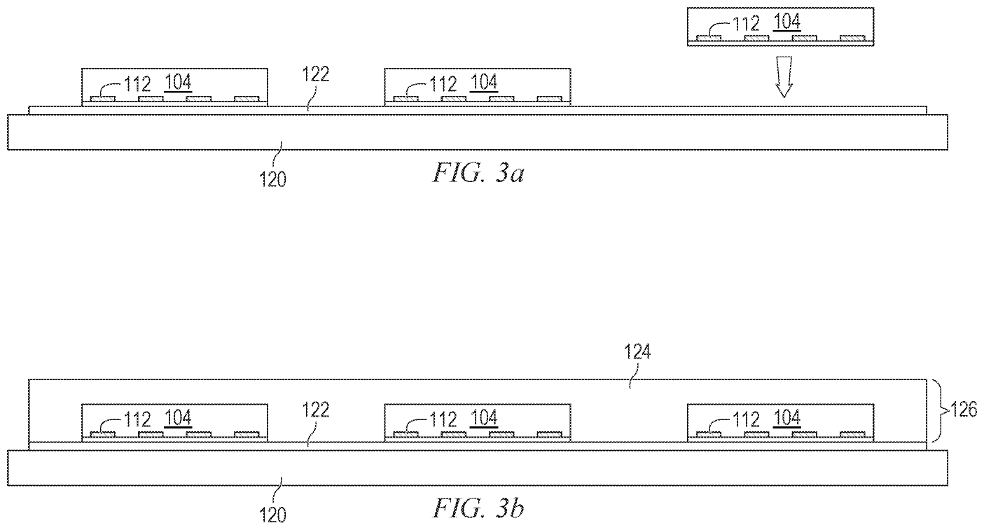

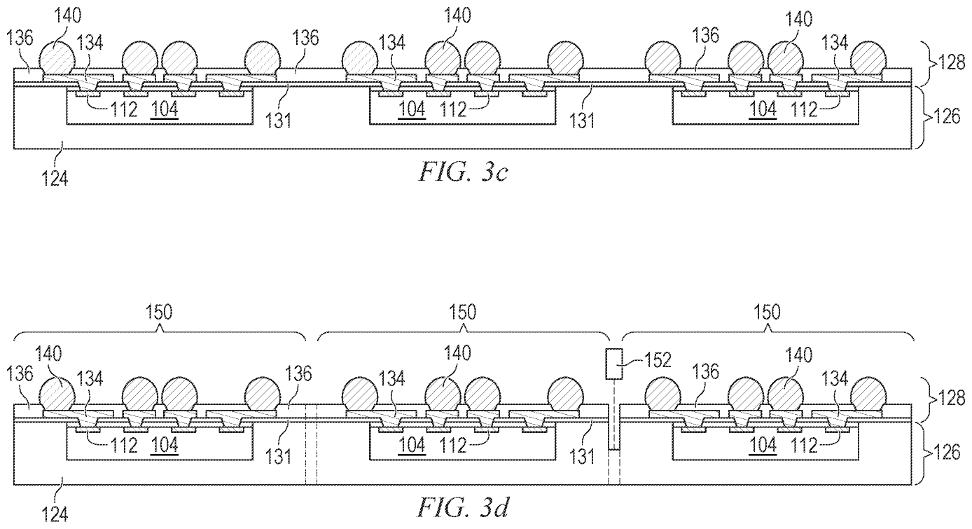

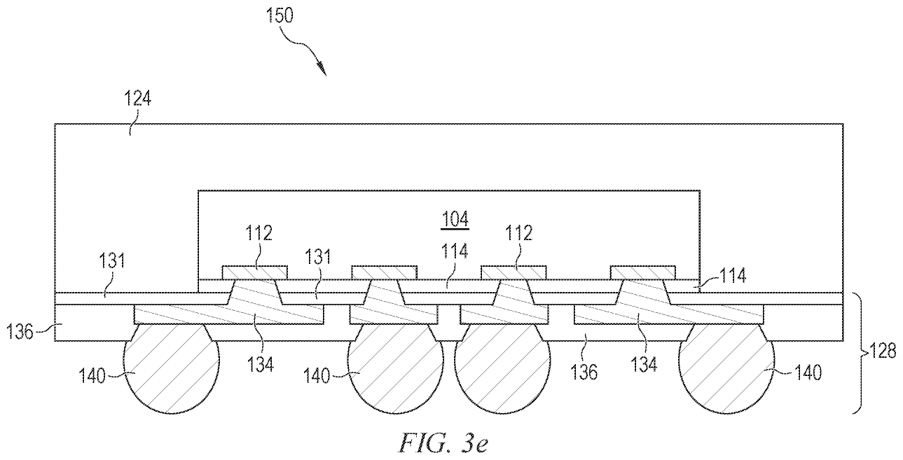

FIGS. 3a-3e illustrate a process of forming embedded wafer-level ball-grid array (eWLB) semiconductor packages. In FIG. 3a, a plurality of semiconductor die 104 are picked and placed onto a carrier 120 containing sacrificial base material such as silicon, polymer, beryllium oxide, glass, or other suitable low-cost, rigid material for structural support. An interface layer or double-sided tape 122 is formed or disposed over carrier 120 as a temporary bonding film, thermal release layer, or UV release layer. To simplify illustration, the packages being formed each includes a single semiconductor die 104 and no other components. In other embodiments, much more complicated packages can be formed with multiple semiconductor die, additional discrete active or passive components, or any other desired electrical components. While carrier 120 is illustrated as large enough for manufacturing three devices together, a typical carrier can handle hundreds or thousands of devices at once.

In FIG. 3b, encapsulant or molding compound 124 is deposited over and around semiconductor die 104 using a paste printing, compressive molding, transfer molding, liquid encapsulant molding, vacuum lamination, spin coating, or other suitable applicator. Encapsulant 124 can be liquid or granular polymer composite material, such as epoxy resin, epoxy acrylate, or another suitable polymer, with or without a suitable filler. Encapsulant 124 is non-conductive, provides structural support, and environmentally protects the semiconductor device from external elements and contaminants.

The combination of semiconductor die 104 and encapsulant 124 forms a reconstituted wafer 126. The term reconstituted wafer indicates that reconstituted wafer 126 can be analogized to semiconductor wafer 100 from which semiconductor die 104 came from. In a sense, semiconductor wafer 100 has been reconstituted with semiconductor die 104 further spread out to facilitate the formation of fan-out interconnect structures over active surfaces 110.

In FIG. 3c, reconstituted wafer 126 is flipped, and a build-up interconnect structure 128 is formed over reconstituted wafer 126. Build-up interconnect structure 128 is so-called because the interconnect structure is formed by building up conductive and insulating layers on top of a substrate, e.g., reconstituted wafer 126. Insulating layer 131 is formed on reconstituted wafer 126 using the methods and materials described above for passivation layer 114. Openings are formed through insulating layer 131 and passivation layer 114 to expose contact pads 112 of semiconductor die 104.

A conductive layer 134 is formed over insulating layer 131 and into the openings in insulating layer 131 and passivation layer 114 to physically contact and electrically connect to contact pads 112. Conductive layer 134 is patterned using a mask, photolithography, chemical etching, laser ablation, jet printing, or another suitable method to form a redistribution layer (RDL) fanning out from contact pads 112. In other embodiments, conductive layer 112 forms a fan-in interconnect structure. The individual conductive traces of conductive layer 134 have one end at a contact pad 112 and have contact pads or capture pads formed at their opposite ends.

Another insulating layer 136 is formed over conductive layer 134 as described for insulating layer 131. Openings are formed through insulating layer 136 to expose contact pads of conductive layer 134. Any number of additional insulating and conductive layers can be interleaved over conductive layer 134 and insulating layer 136 to add RDL layers and allow more complicated signal routing. Only a single RDL layer is illustrated to simplify illustration of the eWLB concept. Additional details of using multiple RDL layers are illustrated below.

An electrically conductive bump material is deposited over conductive layer 134 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 134 using a suitable attachment or bonding process. In one embodiment, the bump material is reflowed by heating the material above its melting point to form bumps 140. In one embodiment, bump 140 is formed over an under-bump metallization (UBM) having a wetting layer, barrier layer, and adhesion layer. Bump 140 can also be compression bonded or thermocompression bonded to conductive layer 134.

In FIG. 3d, encapsulant 124 and build-up interconnect structure 128 are singulated into individual semiconductor packages 150 using a saw blade or laser cutting tool 152. FIG. 3e shows a completed semiconductor package 150. Contact pads 112 are electrically connected to solder bumps 140 by conductive layer 134 and any additional RDL layers that are optionally formed. Some bumps 140 are formed over encapsulant 124, which exacerbates the problem of shorted solder bumps.

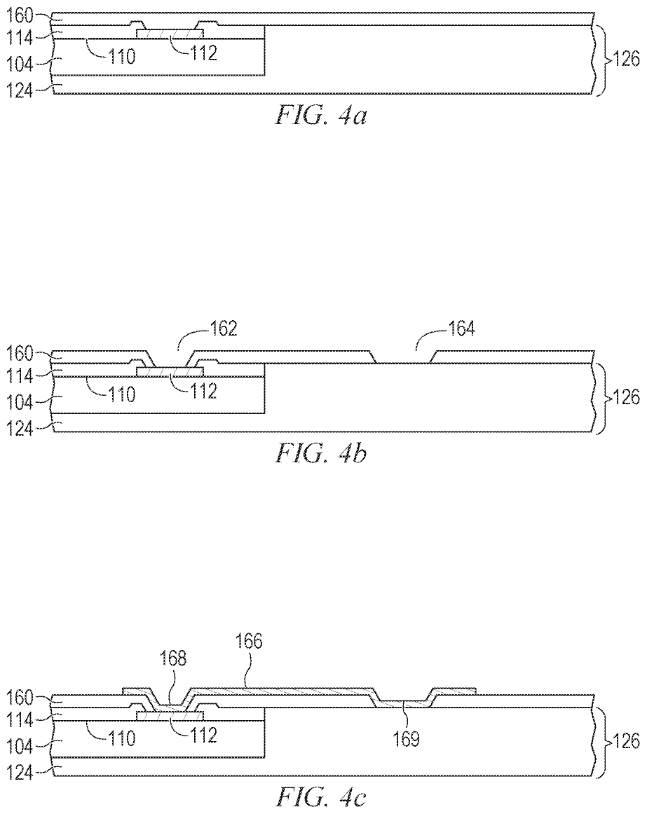

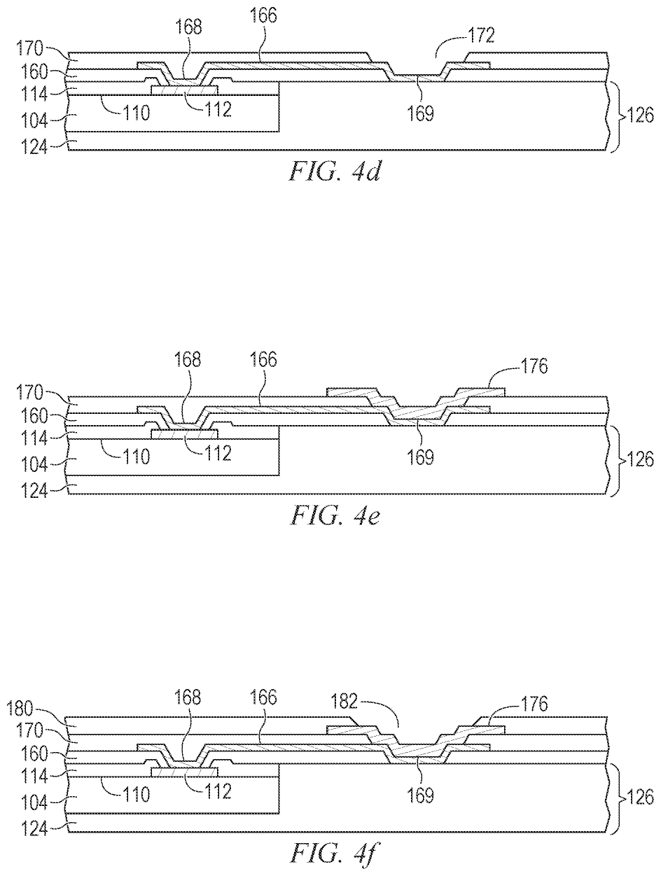

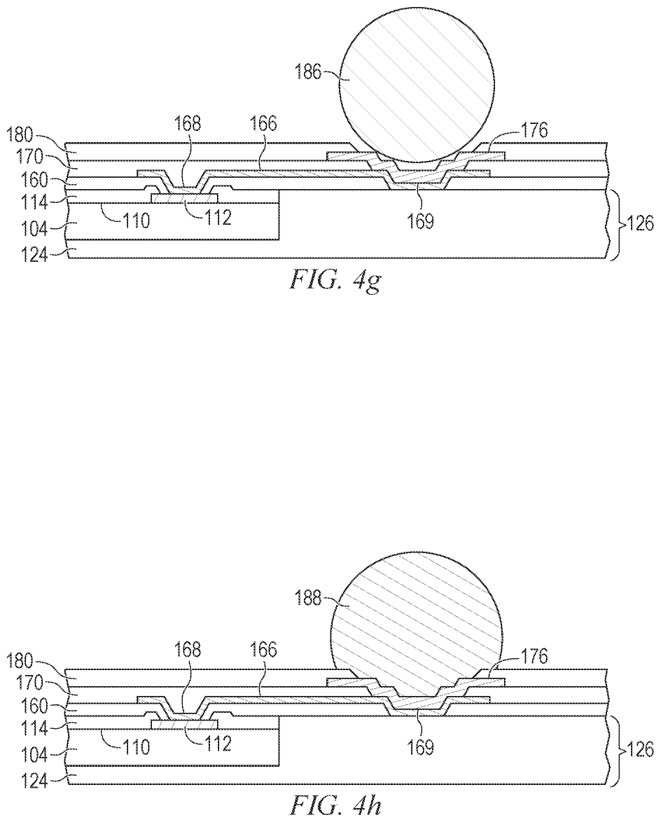

FIGS. 4a-4h illustrate one specific method of forming an RDL layer fanning out from contact pads 112 over encapsulant 124 using dummy openings to reduce short-circuited solder bumps. The RDL method shown in FIGS. 4a-4h is usable in an eWLB package as shown in FIGS. 3a-3e. In FIG. 4a, insulating layer 160 is formed over reconstituted wafer 126 as described above for insulating layer 131. Insulating layer 160 completely covers reconstituted wafer 126.

In FIG. 4b openings 162 and 164 are formed through insulating layer 160. Openings 162-164 are formed by photolithography, laser ablation, chemical etching, or another suitable process. Insulating layer openings mentioned above and below can have openings formed using the same processes. Opening 162 is a via exposing a contact pad 112 of semiconductor die 104 for subsequent electrical interconnect. Opening 164 is a dummy opening that simply exposes encapsulant 124. Opening 164 is only formed partially through insulating layer 160 in other embodiments. A dummy opening means the opening is not required for electrical connection through the insulating layer, but rather for some other purpose. In most embodiments here and below, dummy openings are formed for the purpose of modifying the shape of overlying conductive layers.

In FIG. 4c, a conductive layer 166 is formed over insulating layer 160 as described above for conductive layer 134. Conductive layer 166 is patterned to form a conductive trace extending between openings 162 and 164. Conductive layer 166 extends into opening 162 to form a conductive via 168 physically and electrically contacting contact pad 112. Conductive layer 166 extends into opening 164 to form a recess 169 in, on, or over opening 164. Conductive layer 166 is deposited conformally so that the top surface of the conductive layer is recessed over or into opening 164. Dummy opening 164 has changed the shape of conductive layer 166 from having a flat contact pad to having a recessed contact pad at an end of the conductive trace opposite contact pad 112. Conductive layer 166 forms a circular or other-shaped contact pad at recess 169. The footprint of the contact pad of recess 169 is larger than and completely surrounds a footprint of opening 164.

In FIG. 4d, insulating layer 170 is formed over insulating layer 160 and conductive layer 166 as described above for insulating layer 160. An opening 172 is formed through insulating layer 170 over recess 169. A footprint of opening 172 is larger than opening 164 so that recess 169 is completely exposed within opening 172. The footprint of opening 172 is smaller than the contact pad of conductive layer 166 so that the edges of the contact pad are not exposed within opening 172.

In FIG. 4e, a conductive layer is formed over insulating layer 170 and patterned into a contact pad 176. Multiple contact pads are formed, but only a single contact pad 176 is shown in the limited partial cross-section of FIG. 4e. Contact pad 176 is formed conformally so that the top surface of the contact pad conforms to the underlying combined topology of opening 172 and recess 169. Contact pad 176 is typically circular, or approximately circular, and has a footprint larger than opening 172 so that the contact pad extends out onto the top surface of insulating layer 170 surrounding opening 172.

In FIG. 4f, insulating layer 180 is formed over insulating layer 170 and contact pad 176 as described above for insulating layer 170. An opening 182 is formed through insulating layer 180 over contact pad 176. A footprint of opening 182 is larger than opening 172, so that the recessed portions of contact pad 176 are completely exposed within opening 182, while being smaller than the contact pad so that the edges of the contact pad are not exposed within opening 182.

Contact pad 176 is the contact pad that will ultimately have a solder bump mechanically attached thereto. The process of bumping contact pad 176 commonly starts with disposing a ball of solder 186 onto the contact pad as shown in FIG. 4g. The ball of solder 186 is a loose ball that is not physically attached to contact pad 176 and is therefore able to roll around. Dummy opening 164 in insulating layer 160 results in contact pad 176 having a deep recess that keeps ball 186 trapped over the contact pad instead of allowing the ball to roll elsewhere on reconstituted wafer 126 and potentially short circuiting with another ball of solder. In some embodiments, solder ball 186 rests on a circular ring formed by recess 169 or opening 172, which helps eliminate the possibility that the solder ball can build momentum by rolling on a flat contact pad. In other embodiments, ball 186 rests on a flat bottom surface of contact pad 176 while the topology provided by the underlying recess 169 and opening 172 reduce the likelihood of the bump rolling off the contact pad. Being limited to rolling within the area of recess 169 instead of the entire contact pad reduces the likelihood that the bump will roll near enough to another bump to reflow together with the other bump.

In FIG. 4h, ball 186 is successfully reflowed into a bump 188 that is connected only to contact pad 176. The recess caused by dummy opening 164 and opening 172 kept the ball of solder in place for reflow properly.

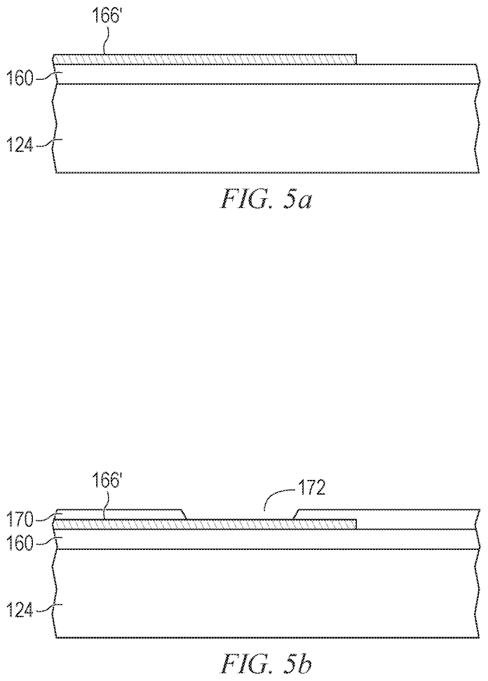

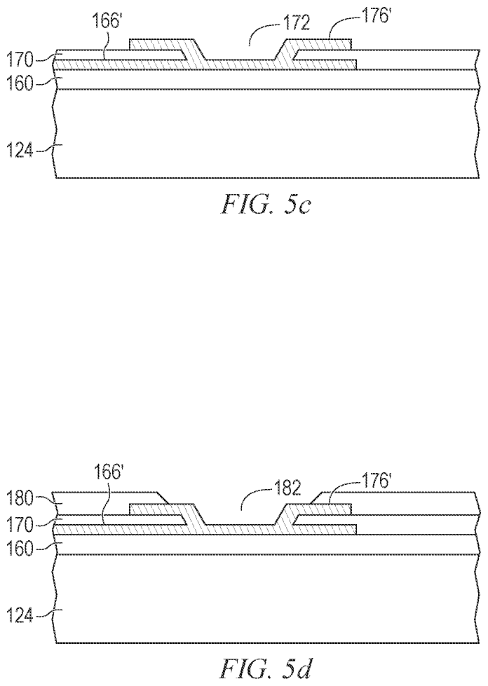

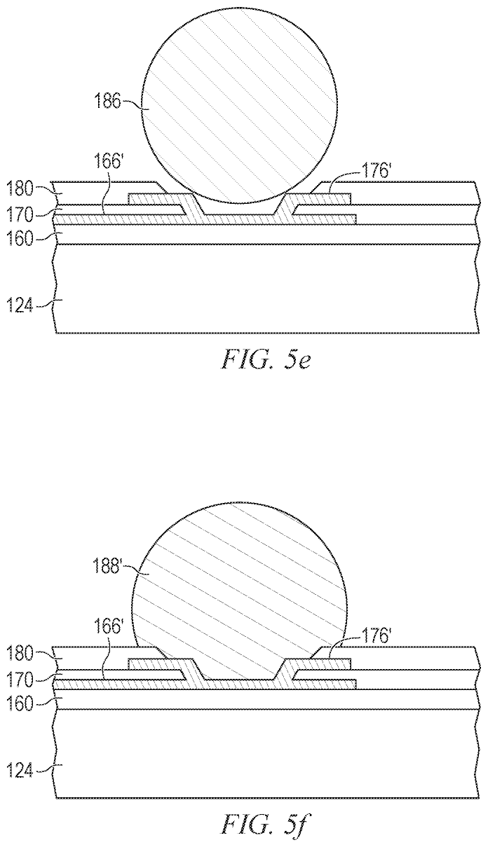

FIGS. 5a-5f show another RDL contact pad topology that can be used along with the topology from FIGS. 4a-4h. FIG. 5a shows the end of another conductive trace 166′ of conductive layer 166 without a dummy opening formed in insulating layer 160. The end of conductive trace 166′ is a circular or other-shaped contact pad. In FIG. 5b, insulating layer 170 is formed with an opening 172 over the contact pad of conductive trace 166′. Conductive trace 166′ is flat under opening 172 in FIG. 5b rather than being recessed as in FIG. 4d.

In FIG. 5c, a contact pad 176′ is formed over insulating layer 170 and on the contact pad of conductive trace 166′ within opening 172. Contact pad 176′ follows the contour of opening 172 but is flat in the middle unlike contact pad 176 in FIG. 4e that also followed the contour of the underlying dummy opening 164. Insulating layer 180 has opening 182 formed over contact pad 176′ in FIG. 5d.

Even without dummy opening 164 through insulating layer 160, opening 172 can still be considered a dummy opening because opening 172 is not strictly necessary and is not typically used in the prior art. In the prior art, the contact pad would only consist of conductive layer 176 remaining as a flat contact pad exposed for bumping. There would be no opening in an insulating layer under conductive layer 176, and the contact pad presented for bumping would simply be a flat conductive layer with only an opening in an insulating layer over the contact pad to keep a ball of solder in place. Conductive layer 176 would have a conductive trace extending away from contact pad 176 or 176′ instead of the conductive traces of the underlying RDL layer 166.

Adding an opening 172 under contact pad 176′ creates a recess in the contact pad that helps keep ball 186 from rolling out of place in FIG. 5e. After reflow in FIG. 5f, bump 188′ remains physically isolated from surrounding bumps because the ball of solder 186 was held in place by the recess in contact pad 176′.

Contact pad 176′ having an opening in only insulating layer 170 underlying the contact pad does not create as deep of a recess as contact pad 176, which also has dummy opening 164 in insulating layer 160. Having a shallower recess overall for contact pad 176′ in FIG. 5f may reduce the protection provided against short-circuiting of solder bumps compared to contact pad 176 in FIG. 4h with a deeper overall recess. The tradeoff is that manufacturing is simpler for contact pad 176′. In one embodiment, contact pads 176 and 176′ are used in combination, with dummy openings 164 formed only under contact pads used for signal transmission while no dummy opening 164 is formed under contact pads for power and ground traces. Bumps 188 for power and ground terminals are usually grouped together such that short circuiting has less of a negative impact because most adjacent bumps are already short-circuited by the underlying conductive layers.

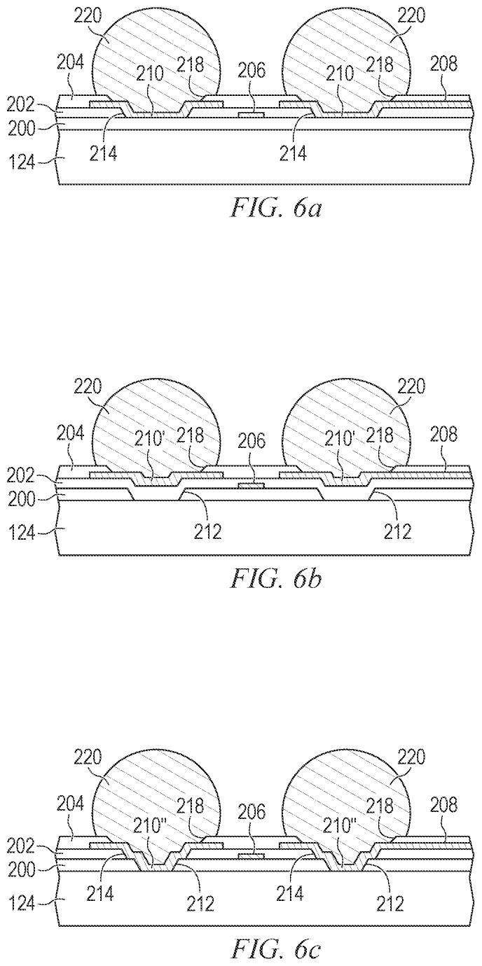

FIGS. 6a-6c illustrate additional contact pad embodiments with dummy openings under the contact pad but without a separate underlying RDL layer with another contact pad to connect to the top contact pad. Each of FIGS. 6a-6c shows a portion of encapsulant 124 with three insulating layers 200, 202, and 204 formed as part of a build-up interconnect structure over a reconstituted wafer. Two conductive redistribution layers (RDL) are formed, a first RDL layer 206 on insulating layer 200 and a second RDL layer 208 on insulating layer 202. The redistribution layers form extensive RDL patterns in other cross-sectional views while only a small part of the RDL and a pair of contact pads is shown in FIGS. 6a-6c.

Contact pad 210 in FIG. 6a, contact pad 210′ in FIG. 6b, and contact pad 210″ in FIG. 6c are all formed as part of the second RDL layer 208 on insulating layer 202. Each contact pad is connected elsewhere on the reconstituted wafer by RDL layer 208 extending laterally across insulating layer 202 from the illustrated contact pad. Contact pads 210, 210′, and 210″ do not have another contact pad as part of the first RDL layer 206 as with contact pads 176 and 176′.

In each FIG. 6a-6c, the build-up interconnect structure is formed as described above. Insulating layer 200 is first formed over the reconstituted wafer. Dummy openings 212, if desired, are formed in insulating layer 200 under the locations where contact pads will be formed. First RDL layer 206 is formed on insulating layer 200. The RDL pattern on insulating layer 200 does not extend to where contact pads 210, 210′, or 210″ are to be formed. Insulating layer 202 is formed on insulating layer 200 and RDL layer 206. Dummy openings 214, if desired, are formed in insulating layer 202 under the locations where contact pads will be formed.

Second RDL layer 208 is formed on insulating layer 202. Second RDL layer 208 includes contact pads 210, 210′, 210″, or any combination thereof as well as conductive traces interconnecting the contact pads to the first RDL layer 206. Insulating layer 204 is formed over RDL layer 208 and contact pads 210, 210′, and 210″. Openings 218 are formed in insulating layer 204 over contact pads 210, 210′, and 210″ for bumping. A single device can use a combination of contact pads 210, 210′ and 210″, or all contact pads can be the same design for each device.

Contact pads 210, 210′, and 210″ are each recessed due to the formation of dummy openings underlying the contact pads. FIG. 6a shows contact pads 210 with dummy openings 214 formed through insulating layer 202 under each contact pad, but without dummy openings 212 formed through insulating layer 200. FIG. 6b shows contact pads 210′ with dummy openings 212 formed through insulating layer 200, but without dummy openings 214 formed through insulating layer 202. FIG. 6c shows contact pads 210″ with both dummy openings 212 and dummy openings 214 formed under each contact pad. In any of the illustrated cases, the recessed contact pads keep balls of solder in place during reflow so that solder bumps 220 can be formed with reduced risk of short circuit between the bumps.

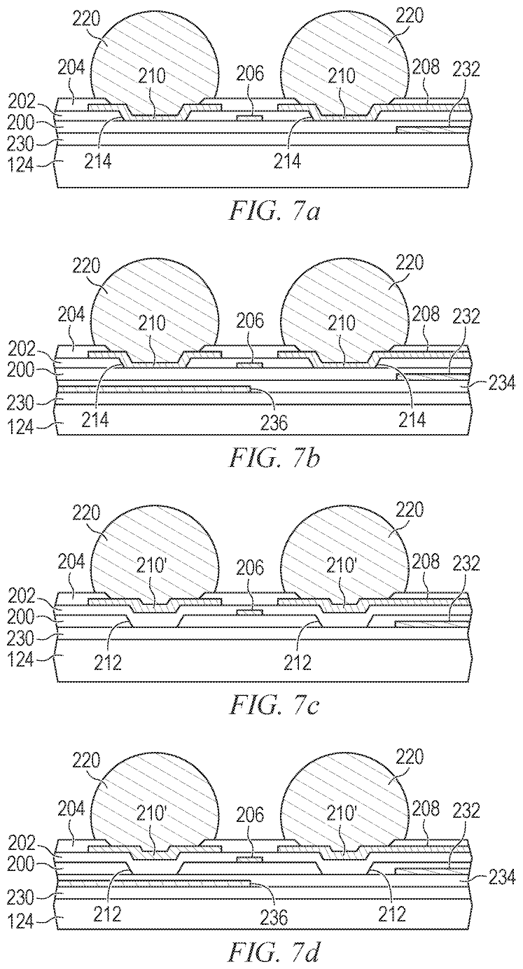

FIGS. 4h, 5f, and 6a-6c all show a contact pad being formed as part of the second RDL layer 208 over encapsulant 124, but each of those contact pad topologies can be used at any RDL level. When more complex signal routing is required, additional RDL levels can be formed under the layers used for contact pads, and then the same contact pad RDL layers can be formed thereon. FIG. 7a shows a single extra RDL layer with insulating layer 230 and RDL layer 232 formed under insulating layers 200-204 and RDL layers 206-208 from FIG. 6a.

FIG. 7a is the same as FIG. 6a except for an additional RDL layer is formed over encapsulant 124 and under insulating layer 200. Insulating layer 202 with dummy opening 214 is now the third insulating layer instead of the second. Contact pad 210 is formed as part of the third RDL layer in the stack instead of the second.

FIG. 7b shows contact pad 210 formed as part of the fourth RDL layer in the stack with two additional RDL layers, including insulating layer 230, RDL layer 232, insulating layer 234, and RDL layer 236, formed under insulating layer 200. FIGS. 7c and 7d show contact pad 210′ from FIG. 6b formed at higher RDL layers. In FIG. 7c, one extra RDL layer 232 is formed under insulating layer 200. In FIG. 7c, two extra RDL layers 232 and 236 are formed under insulating layer 200. Any of the previously illustrated or described embodiments can be formed at any RDL layer.

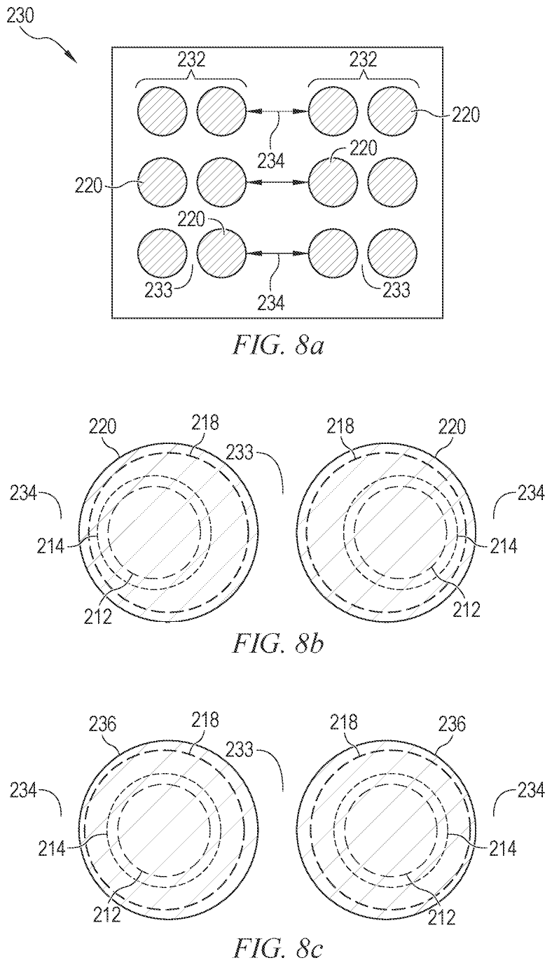

In all the above embodiments, any dummy openings have been formed concentric with the overlying solder bumps. In some embodiments, the pitch between bumps may not be consistent across the entire reconstituted wafer. FIG. 8a shows an embodiment with reconstituted wafer 230 where solder bumps 220 are formed in two groups 232. Bumps 220 have a smaller bump pitch within groups 232 than between the groups. The gap 233 between bumps 220 within group 232 is around half of the gap 234 between bumps of adjacent groups. Gap 234 between the different groups 232 can be within a single unit or across a saw street of reconstituted wafer 230.

To provide added benefit where bump pitch is smallest, e.g., within groups 232, FIG. 8b shows the dummy openings 212 and/or 214 formed off-centered within openings 218. The contact pad recesses caused by the dummy openings are formed further away from the closer adjacent contact pad. Dummy openings 212 and 214 have a more consistent pitch width across reconstituted wafer compared to the final bumps 220. When balls of solder are placed on the contact pad the balls are held within the recesses at a more consistent pitch across the entire reconstituted wafer 230.

Another option to reduce the likelihood of solder balls rolling into each other and short circuiting is to place the solder balls within their recesses already rolled toward each other. FIG. 8c shows dummy openings 212 and 214 formed concentrically with opening 218 in the top insulating layer. Balls of solder 236 are placed onto the contact pads within the recesses formed by the dummy openings. Balls 236 are placed on the flat bottom surfaces of the recesses against the ridge or edge of the bottom surface toward the smaller gap 233. Placing balls 236 against the edge of the recess initially makes it harder for the balls to roll toward each other prior to reflow and short circuit. The edges provided by openings 212 and 214 are initially stopping solder ball 236 from rolling toward smaller gap 233 and gathering momentum to escape the contact pad recesses.

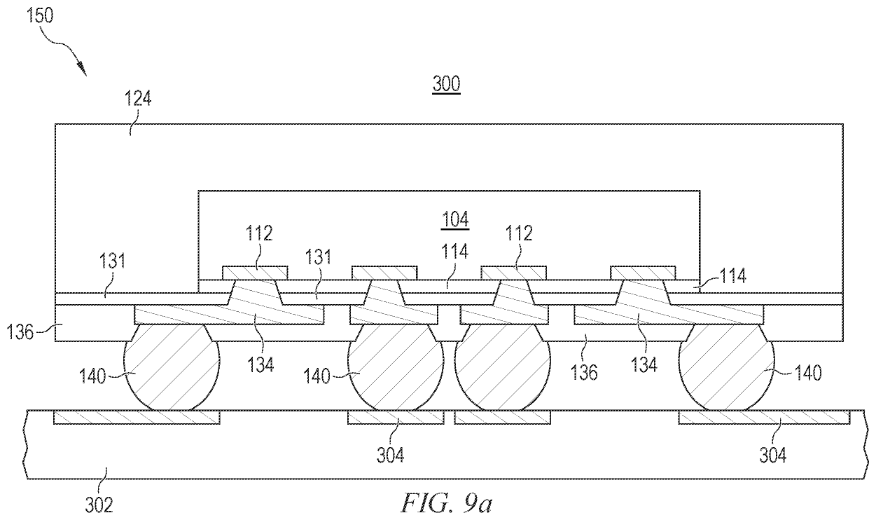

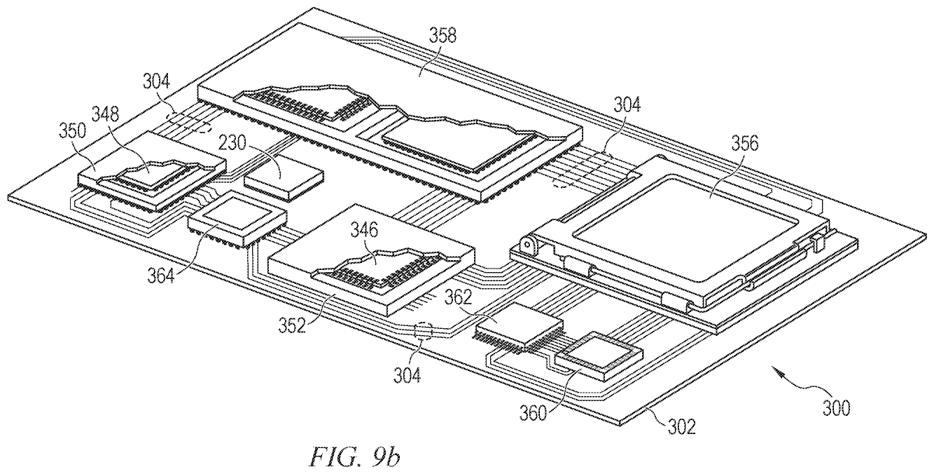

FIGS. 9a and 9b illustrate integrating the above-described semiconductor packages, e.g., semiconductor package 150 with any combination of the above-described RDL and contact pad topologies, into a larger electronic device 300. FIG. 9a illustrates a partial cross-section of semiconductor package 150 mounted onto a printed circuit board (PCB) or other substrate 302 as part of electronic device 300. Bumps 140 are reflowed onto conductive layer 304 of PCB 302 to physically attach and electrically connect semiconductor package 150 to the PCB. In other embodiments, thermocompression or another suitable attachment and connection methods are used. In some embodiments, an adhesive or underfill layer is used between semiconductor package 150 and PCB 302. Semiconductor die 104 is electrically coupled to conductive layer 304 through bumps 140 and conductive layer 134.

FIG. 9b illustrates electronic device 300 having a chip carrier substrate or PCB 302 with a plurality of semiconductor packages disposed on a surface of PCB 302, including semiconductor package 150. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 9b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor die;
depositing an encapsulant over the semiconductor die to form a reconstituted wafer;
forming a first insulating layer over the reconstituted wafer;
forming a first dummy opening in the first insulating layer; and
forming a first conductive layer on the first insulating layer including a first contact pad over the first dummy opening.

2. The method of claim 1, further including:
forming a second insulating layer over the first conductive layer;
forming an opening in the second insulating layer to expose the first contact pad; and
forming a second contact pad on the first contact pad and second insulating layer.

3. The method of claim 1, further including:
forming a redistribution layer over the reconstituted wafer; and
forming the first insulating layer over the redistribution layer.

4. The method of claim 1, further including:
forming a second insulating layer over the first insulating layer; and
forming the first conductive layer over the second insulating layer.

5. The method of claim 4, further including forming a second dummy opening in the second insulating layer over the first dummy opening.

6. The method of claim 1, further including forming the first dummy opening off-centered to the first contact pad.

7. A method of making a semiconductor device, comprising:
providing a substrate;
forming a first insulating layer over the substrate;
forming a first opening in the first insulating layer; and
forming a first conductive layer including a first contact pad over the first opening.

8. The method of claim 7, further including:
forming a second insulating layer over the first conductive layer;
forming a second opening in the second insulating layer over the first contact pad; and
forming a second contact pad on the first contact pad and second insulating layer.

9. The method of claim 7, further including:
forming a redistribution layer over the substrate; and
forming the first insulating layer over the redistribution layer.

10. The method of claim 7, further including:
forming a second insulating layer over the first insulating layer; and
forming the first conductive layer over the second insulating layer.

11. The method of claim 10, further including forming a second opening in the second insulating layer over the first opening.

12. The method of claim 7, further including forming a second insulating layer under the first insulating layer.

13. The method of claim 7, further including forming the first opening off-centered to the first contact pad.

14. A semiconductor device, comprising:
a semiconductor die;
an encapsulant deposited over the semiconductor die to form a reconstituted wafer;
a first insulating layer formed over the reconstituted wafer;
a dummy opening formed in the first insulating layer; and
a first conductive layer formed on the first insulating layer including a first contact pad over the dummy opening.

15. The semiconductor device of claim 14, further including:
a second insulating layer formed over the first conductive layer;
an opening formed in the second insulating layer to expose the first contact pad; and
a second contact pad formed on the first contact pad and second insulating layer.

16. The semiconductor device of claim 14, further including a redistribution layer formed over the reconstituted wafer, wherein the first insulating layer is formed over the redistribution layer.

17. The semiconductor device of claim 14, further including a second insulating layer formed over the first insulating layer, wherein the first conductive layer is formed over the second insulating layer.

18. The semiconductor device of claim 17, further including a second dummy opening formed in the second insulating layer over the first dummy opening.

19. The semiconductor device of claim 14, wherein the first dummy opening is formed off-centered to the first contact pad.

20. A semiconductor device, comprising:
a substrate;
a first insulating layer formed over the substrate;
a first opening formed in the first insulating layer; and
a first conductive layer including a first contact pad formed over the first opening.

21. The semiconductor device of claim 20, further including:
a second insulating layer formed over the first conductive layer;
a second opening formed in the second insulating layer over the first contact pad; and
a second contact pad formed on the first contact pad and second insulating layer.

22. The semiconductor device of claim 20, further including a redistribution layer formed over the substrate, wherein the first insulating layer is formed over the redistribution layer.

23. The semiconductor device of claim 20, further including a second insulating layer formed over the first insulating layer, wherein the first conductive layer is formed over the second insulating layer.

24. The semiconductor device of claim 23, further including a second opening formed in the second insulating layer over the first opening.

25. The semiconductor device of claim 20, wherein the first opening is formed off-centered to the first contact pad.
